(19) United States
(12) Patent Application Publication
(10) Pub. No.: US 2023/0051737 A1
(43) Pub. Date: Feb. 16, 2023

(54) APPARATUS, METHOD, AND COMPUTER PROGRAM FOR EXECUTING SIMULATION ON BASIS OF DIGITAL TWIN SERVICE

(71) Applicant: KT CORPORATION, Seongnam-si Gyeonggi-do (KR)

(72) Inventors: Jeong Hee HONG, Seoul (KR); Il Myung KIM, Hanam-si (KR); Won Woo JUNG, Anyang-si (KR); Byoung Suk JI, Seoul (KR)

(21) Appl. No.: 17/767,618

(22) PCT Filed: Sep. 29, 2020
(86) PCT No.: PCT/KR2020/013314

§ 371 Date: Apr. 8, 2022

(30) Foreign Application Priority Data
Oct. 14, 2019 (KR) 10-2019-0126625

(51) Int. Cl. G06F 30/20

(52) U.S. Cl. CPC G06F 30/20

(57) ABSTRACT

A simulation device configured to perform a simulation based on a digital twin service includes a creation unit configured to create a simulation model based on model design data; an identification unit configured to identify at least one intrinsic parameter of the created simulation model and at least one input value related to the intrinsic parameter; an output unit configured to output an estimated output value which is produced from the simulation model depending on the input value based on the intrinsic parameter; a correlation analysis unit configured to analyze a correlation between the intrinsic parameter and the estimated output value; a selection unit configured to select at least one representative intrinsic parameter from among the at least one intrinsic parameter depending on the analyzed correlation; a collection unit configured to collect real sensor data related to the representative intrinsic parameter from a real model constructed based on the model design data; an update unit configured to update the at least one representative intrinsic parameter based on the collected real sensor data and the estimated output value; and a simulation unit configured to perform a simulation by applying the updated representative intrinsic parameter to the simulation model.

### TECHNICAL FIELD

The present disclosure relates to an apparatus, method and computer program for executing a simulation.

### BACKGROUND

Digital Twin is the technology for acquiring accurate information about characteristics of real assets by creating twins of real objects on a computer and simulating situations that may occur in reality with a computer. This technology makes it possible to know conditions, productivity, operation scenarios, and the like of real assets and thus can improve the efficiency across production and services of various industries. Therefore, this technology has attracted a lot of attention recently.

In general, a digital twin is developed directly by a domain expert using a domain-specific simulator and data. Therefore, whenever a digital twin for a new domain needs to be developed, the existing domain cannot be reused and the domain expert has to re-implement a domain. Also, the existing digital twin simulation technology has a limitation in that it cannot reflect member characteristics of a real model.

Meanwhile, the developed digital twin is composed of an updated simulation model and a simulation engine for executing the simulation model. The simulation engine may incur a license fee.

Since the simulation model of the developed digital twin is generally a probabilistic model, iterative simulation is required. Also, it takes a considerable amount of time for the simulation engine to execute one simulation, resulting in an increase in overall simulation time. For this reason, it may be difficult to analyze various scenarios within a limited time or to provide services in real time.
Patent Document 1: Korean Patent Laid-open Publication No. 2016-0133615 (published on Nov. 23, 2016)

### DISCLOSURE OF THE INVENTION

### Problems to be Solved by the Invention

The present disclosure is conceived to solve the above-described problems of the prior art and to select a representative intrinsic parameter among intrinsic parameters of a simulation model created based on model design data and update the selected representative intrinsic parameter based on real sensor data related to the representative intrinsic parameter and an estimated output value of the representative intrinsic parameter (an estimated output value depending on an input value of the representative intrinsic parameter output from the simulation model). Also, the present disclosure is conceived to perform a simulation by applying the updated representative intrinsic parameter to the simulation model. However, the problems to be solved by the present disclosure are not limited to the above-described problems. There may be other problems to be solved by the present disclosure.

### Means for Solving the Problems

According to at least one example embodiment, simulation device that performs a simulation based on a digital twin service may include a creation unit configured to create a simulation model based on model design data; an identification unit configured to identify at least one intrinsic parameter of the created simulation model and at least one input value related to the intrinsic parameter; an output unit configured to output an estimated output value which is produced from the simulation model depending on the input value based on the intrinsic parameter; a correlation analysis unit configured to analyze a correlation between the intrinsic parameter and the estimated output value; a selection unit configured to select at least one representative intrinsic parameter from among the at least one intrinsic parameter depending on the analyzed correlation; a collection unit configured to collect real sensor data related to the representative intrinsic parameter from a real model constructed based on the model design data; an update unit configured to update the at least one representative intrinsic parameter based on the collected real sensor data and the estimated output value; and a simulation unit configured to perform a simulation by applying the updated representative intrinsic parameter to the simulation model

According to at least one other example embodiment, a simulation method for performing a simulation based on a digital twin service may include creating a simulation model based on model design data; identifying at least one intrinsic parameter of the created simulation model and at least one input value related to the intrinsic parameter; outputting an estimated output value which is produced depending on the input value from the simulation model based on the intrinsic parameter; analyzing a correlation between the intrinsic parameter and the estimated output value; selecting at least one representative intrinsic parameter from among the at least one intrinsic parameter depending on the analyzed correlation; collecting real sensor data related to the representative intrinsic parameter from a real model constructed based on the model design data; and updating the at least one representative intrinsic parameter based on the collected real sensor data and the estimated output value.

According to at least one other example embodiment, A computer-readable recording medium having stored thereon computer-executable instructions that, in response to execution, cause a computing device to create a simulation model based on model design data, wherein the computer-executable instructions cause the computing device to: identify at least one intrinsic parameter of the created simulation model, select at least one representative intrinsic parameter from among the at least one identified intrinsic parameter, collect real sensor data related to the representative intrinsic parameter from a real model constructed based on the model design data, update the at least one representative intrinsic parameter based on the collected real sensor data, and perform a simulation by applying the updated representative intrinsic parameter to the simulation model.

This summary is provided by way of illustration only and should not be construed as limiting in any manner. Besides the above-described exemplary embodiments, there may be additional exemplary embodiments that become apparent by reference to the drawings and the detailed description that follows.

### Effects of the Invention

According to any one of the above-described means for solving the problems, it is possible to select a representative intrinsic parameter among intrinsic parameters of a simulation model created based on model design data and update the selected representative intrinsic parameter based on real sensor data related to the representative intrinsic parameter and an estimated output value of the representative intrinsic parameter (an estimated output value output from the simulation model depending on an input value of the representative intrinsic parameter). Also, according to the present disclosure, it is possible to perform a simulation by applying the updated representative intrinsic parameter to the simulation model. Therefore, according to the present disclosure, it is possible to reflect the current state of a real model constructed based on the model design data in the simulation model and thus possible to predict a future risk by simulation in advance.

Further, according to the present disclosure, it is possible to create a digital twin specialized for each domain regardless of the domain type and provide a digital twin-based service. For example, according to the present disclosure, it is possible to provide a plurality of simulation services (simulation services through a plurality of surrogate models) reconstructed based on a bridge simulation model corresponding to a bridge domain.

### BRIEF DESCRIPTION OF THE DRAWINGS

FIG. 1 is a block diagram illustrating a device for performing a simulation in accordance with an embodiment of the present disclosure.

FIG. 2 is a configuration diagram of a simulation operating system and a service system in accordance with an embodiment of the present disclosure.

FIG. 3A is an example depiction to explain a method for performing a simulation of a bridge in accordance with the embodiment of the present disclosure.

FIG. 3B is an example depiction to explain a method for performing a simulation of a bridge in accordance with the embodiment of the present disclosure.

FIG. 3C is an example depiction to explain a method for performing a simulation of a bridge in accordance with the embodiment of the present disclosure.

FIG. 4A is an example depiction to explain a method for performing a simulation of an intersection in accordance with the embodiment of the present disclosure.

FIG. 4B is an example depiction to explain a method for performing a simulation of an intersection in accordance with the embodiment of the present disclosure.

FIG. 5A is an example depiction to explain a method for creating a surrogate model in accordance with the embodiment of the present disclosure.

FIG. 5B is an example depiction to explain a method for creating a surrogate model in accordance with the embodiment of the present disclosure.

FIG. 6 is a flowchart illustrating a method for performing a simulation in accordance with an embodiment of the present disclosure.

FIG. 7 is a flowchart illustrating a method for performing a simulation of a bridge in accordance with an embodiment of the present disclosure.

FIG. 8 is a flowchart illustrating a method for performing a simulation of an intersection in accordance with an embodiment of the present disclosure.

### BEST MODE FOR CARRYING OUT THE INVENTION

Hereafter, example embodiments will be described in detail with reference to the accompanying drawings so that the present disclosure may be readily implemented by those skilled in the art. However, it is to be noted that the present disclosure is not limited to the example embodiments but can be embodied in various other ways. In the drawings, parts irrelevant to the description are omitted for the simplicity of explanation, and like reference numerals denote like parts through the whole document.

Throughout this document, the term “connected to” may be used to designate a connection or coupling of one element to another element and includes both an element being “directly connected” another element and an element being “electronically connected” to another element via another element. Further, it is to be understood that the terms “comprises,” “includes,” “comprising,” and/or “including” means that one or more other components, steps, operations, and/or elements are not excluded from the described and recited systems, devices, apparatuses, and methods unless context dictates otherwise; and is not intended to preclude the possibility that one or more other components, steps, operations, parts, or combinations thereof may exist or may be added.

Throughout this document, the term “unit” may refer to a unit implemented by hardware, software, and/or a combination thereof. As examples only, one unit may be implemented by two or more pieces of hardware or two or more units may be implemented by one piece of hardware.

Throughout this document, a part of an operation or function described as being carried out by a terminal or device may be implemented or executed by a server connected to the terminal or device. Likewise, a part of an operation or function described as being implemented or executed by a server may be so implemented or executed by a terminal or device connected to the server.

Hereinafter, embodiments of the present disclosure will be explained in detail with reference to the accompanying drawings.

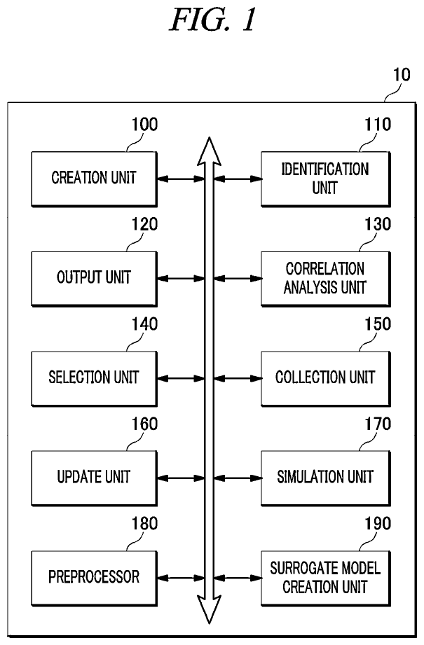

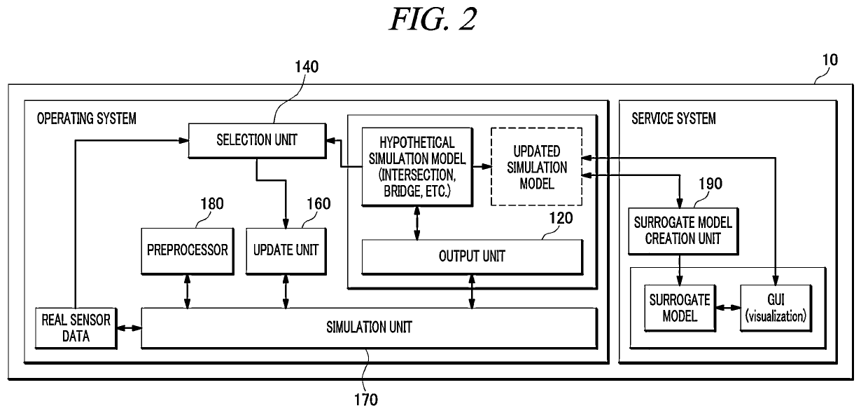

FIG. 1 is a block diagram illustrating a device for performing a simulation in accordance with an embodiment of the present disclosure. FIG. 2 is a configuration diagram of a simulation operating system and a service system in accordance with an embodiment of the present disclosure.

Referring to FIG. 1 and FIG. 2, a simulation device 10 is configured to perform a simulation based on a digital twin service, and may include a creation unit 100, an identification unit 110, an output unit 120, a correlation analysis unit 130, a selection unit 140, a collection unit 150, an update unit 160, a simulation unit 170, a preprocessor 180 and a surrogate model creation unit 190. However, the simulation device 10 depicted in FIG. 2 is just an example embodiment of the present disclosure, and various modifications can be made based on the components depicted in FIG. 2.

The creation unit 100 may create a simulation model (hypothetical simulation) based on model design data. For example, the creation unit 100 may parse a reinforced concrete structure diagram of a bridge structure based on bridge design data and create a three-dimensional simulation model of the bridge structure using the parsed reinforced concrete structure diagram.

The identification unit 110 may identify, from the created simulation model, at least one intrinsic parameter representing a characteristic of the simulation model and at least one input value related to the identified intrinsic parameter.

The output unit 120 may output an estimated output value which can be produced from the simulation model depending on an input value from the simulation model based on the intrinsic parameter of the simulation model.

The correlation analysis unit 130 may analyze a correlation between the intrinsic parameter and the estimated output value.

The selection unit 140 may select at least one representative intrinsic parameter from among the at least one intrinsic parameter of the simulation model depending on the analyzed correlation.

The collection unit 150 may collect real sensor data related to the representative intrinsic parameter from a real model constructed based on the model design data.

The preprocessor 180 may preprocess the collected real sensor data to be applied to the simulation model in association with the at least one representative intrinsic parameter.

### First Embodiment

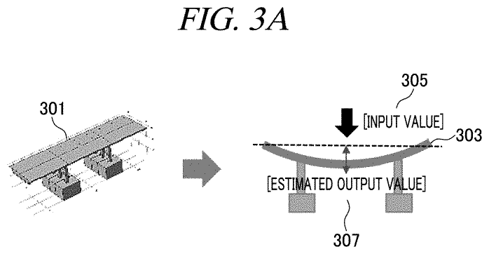

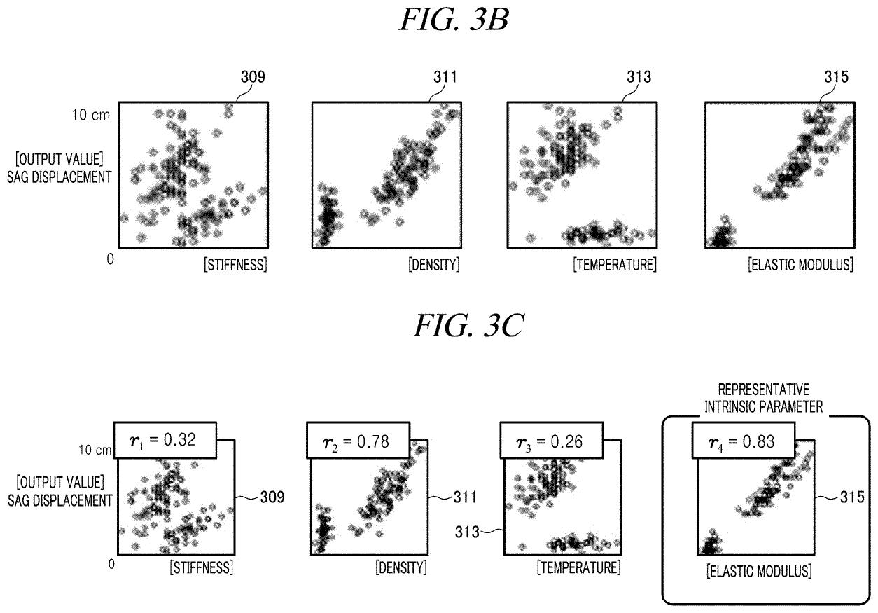

Referring to FIG. 3A through FIG. 3C, the creation unit 100 may create a simulation model 301 of a bridge 303 based on bridge design data (i.e., a bridge design drawing). In this case, the creation unit 100 may create the simulation model 301 of a bridge based on default values of material properties of general members used in the bridge 303.

The identification unit 110 may identify, through the simulation model 301 of the bridge 303, intrinsic parameters (e.g., stiffness, length, mass, temperature, density, elastic modulus, damping coefficient, and the like) representing design characteristics of the bridge 303 in the design of the bridge 303.

The identification unit 110 may identify input values 305 (e.g., a load of the bridge 303) of the simulation model 301 related to a plurality of intrinsic parameters of the simulation model 301 of the bridge 303.

When the input values 305 related to the plurality of intrinsic parameters of the simulation model 301 of the bridge 303 are input into the simulation model 301, the output unit 120 may output, through the simulation model 301, estimated output values 307 (e.g., displacement for each member of the bridge 303) that can be output for each member of the bridge 303.

The output unit 120 may set a range of variation of an intrinsic parameter of the bridge 303 and output an estimated output value of the bridge situation which can be produced depending on an input value from the simulation model 301 of the bridge 303 to which the set range of variation of the intrinsic parameter is applied. For example, since reinforced concrete has a default density d of 1,150 km/m³, the output unit 120 may set a range of variation of the at least one intrinsic parameter “density” from 1,100 km/m³ to 1,200 km/m³ (generally variable range of density), and the output unit 120 may set a range of variation of the at least one intrinsic parameter “temperature” from −30° to 50°.

When the input value “load” is input into the simulation model 301 of the bridge 303, the output unit 120 may output an estimated output value of each intrinsic parameter that can be produced within a range of variation of each intrinsic parameter.

The correlation analysis unit 130 may derive a distribution map of an estimated output value of each intrinsic parameter depending on the input value “load” of the bridge. For example, referring to FIG. 3B, the correlation analysis unit 130 may derive a distribution map 309 of an estimated output value of the intrinsic parameter “stiffness” of the bridge 303, a distribution map 311 of an estimated output value of the intrinsic parameter “density”, a distribution map 313 of an estimated output value of the intrinsic parameter “temperature” and a distribution map 315 of an estimated output value of the intrinsic parameter “elastic modulus” depending on the input value “load” of the bridge 303.

The correlation analysis unit 130 may derive a distribution map of the estimated output value output in relation to each intrinsic parameter depending on the input value for each intrinsic parameter of the bridge 303, and analyze the derived distribution map to derive a correlation between the intrinsic parameter and the estimated output value. For example, the correlation analysis unit 130 may derive a correlation (correlation coefficient r) between an intrinsic parameter and an estimated output value from a distribution map of the estimated output value of each intrinsic parameter by using a Pearson correlation coefficient formula.

The selection unit 140 may select a representative intrinsic parameter from among a plurality of intrinsic parameters based on the correlation between the intrinsic parameter and the estimated output value derived for each intrinsic parameter. For example, referring to FIG. 3C, the selection unit 140 may select, as a representative intrinsic parameter of the bridge 303, an intrinsic parameter (i.e., the intrinsic parameter “elastic modulus”) with a high Pearson correlation coefficient r between the intrinsic parameter and the estimated output value from among a plurality of intrinsic parameters.

Meanwhile, as for the intrinsic parameter “elastic modulus” selected as the representative intrinsic parameter of the bridge 303, it is difficult to measure real sensor data corresponding to the “elastic modulus” from a real model of the bridge 303 in real time.

The “elastic modulus” has an engineering relationship with “natural frequency” (see Equation 1), and the “natural frequency” can be extracted from acceleration data.

$$w {=}^{\sqrt{\frac{k}{m}}} , k {=}^{{w}^{2} \times m} \qquad [ Equation 1 ]$$

Herein, w is the natural frequency, k is the elastic modulus, and m is the mass.

The collection unit 150 may collect an intrinsic parameter “acceleration data” related to the intrinsic parameter “elastic modulus” from an acceleration sensor installed in the real model of the actually constructed bridge 303.

The preprocessor 180 may derive data “elastic modulus” as the representative intrinsic parameter by preprocessing the collected acceleration data. Specifically, the preprocessor 180 may extract a natural frequency from the collected acceleration data through FFT transformation and derive the “elastic modulus” from the extracted natural frequency by using Equation 1.

### Second Embodiment

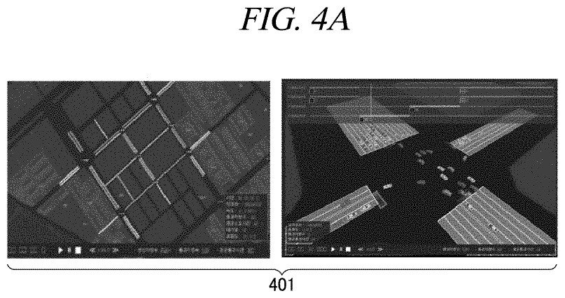

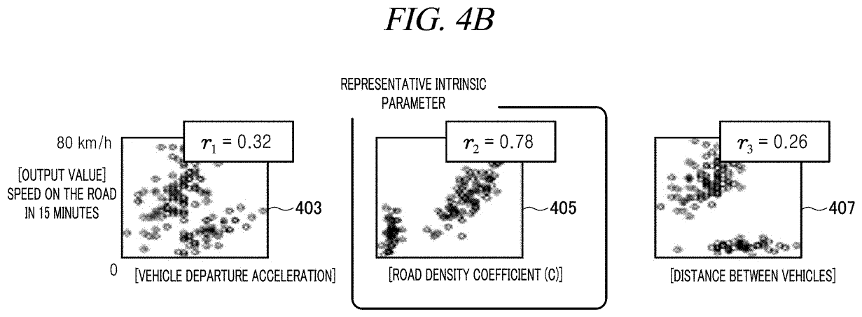

Referring to FIG. 4A and FIG. 4B, the creation unit 100 may create a simulation model 401 of an intersection based on intersection design data (i.e., an intersection design drawing). In this case, the creation unit 100 may create the simulation model 401 of an intersection based on default values of material properties of general members used in the intersection.

The identification unit 110 may identify, through the simulation model 401 of the intersection, intrinsic parameters (e.g., vehicle departure acceleration, distance between vehicles, road density coefficient, and the like) representing design characteristics of the intersection in the design of the intersection.

The identification unit 110 may identify input values (e.g., speed for road, speed change by time, signal cycle for intersection, and the like) of the simulation model 401 related to a plurality of intrinsic parameters of the simulation model 401 of the intersection.

When the input values related to the plurality of intrinsic parameters of the simulation model 401 of the intersection are input into the simulation model 401, the output unit 120 may output, through the simulation model 401, estimated output values (e.g., speed for road in the future) that can be output for each road of the intersection.

The output unit 120 may set a range of variation of an intrinsic parameter of the intersection and output an estimated output value of the intersection situation which can be produced depending on an input value from the simulation model 401 of the intersection to which the set range of variation of the intrinsic parameter is applied. For example, if a vehicle speed is 30 km/h and the default number of vehicles per lane at the intersection is 6, the output unit 120 may set a range of variation of at least one intrinsic parameter “number of vehicles” with respect to an average vehicle speed of 30 km/h from 3 to 9 (generally variable range of number of vehicles). Alternatively, if a vehicle default departure acceleration at the intersection is 10 km/s², the output unit 120 may set a range of variation of at least one intrinsic parameter “vehicle acceleration” from 2 km/s² to 20 km/s² (generally variable range of vehicle acceleration).

When the input value “average vehicle speed” is input into the simulation model 401 of the intersection, the output unit 120 may output an estimated output value of each intrinsic parameter that can be produced within a range of variation of each intrinsic parameter.

The correlation analysis unit 130 may derive a distribution map of an estimated output value of each intrinsic parameter depending on the input value “average vehicle speed”.

The correlation analysis unit 130 may derive a distribution map of the estimated output value output in relation to each intrinsic parameter depending on the input value “average vehicle speed” for each intrinsic parameter of the intersection, and analyze the derived distribution map to derive a correlation (e.g., Pearson correlation coefficient) between the intrinsic parameter and the estimated output value.

The selection unit 140 may select a representative intrinsic parameter from among a plurality of intrinsic parameters based on the correlation between the intrinsic parameter and the estimated output value derived for each intrinsic parameter. For example, referring to FIG. 4B, the selection unit 140 may select, as a representative intrinsic parameter, an intrinsic parameter (i.e., the intrinsic parameter “road density coefficient”) with a high correlation coefficient from among correlation coefficients between intrinsic parameters and estimated output values derived by analyzing a distribution map 403 of an estimated output value of the intrinsic parameter “vehicle departure acceleration”, a distribution map 405 of an estimated output value of the intrinsic parameter “road density coefficient” and a distribution map 407 of an estimated output value of the intrinsic parameter “distance between vehicles” depending on the input value “average vehicle speed” (80 km/h).

Meanwhile, as for the intrinsic parameter “road density coefficient” selected as the representative intrinsic parameter of the intersection, it is difficult to determine the locations of all vehicles and the “road density coefficient” changes every moment depending on the vehicle speed. Therefore, realistically, it is difficult to measure data (e.g., the number of vehicles per unit road length of 1 km) corresponding to the “road density coefficient”.

Since the “road density coefficient” has an engineering functional relationship (road density=f (speed)) with the “vehicle speed”, the “road density coefficient” can be derived from the “vehicle speed”.

The collection unit 150 may collect vehicle speed data related to the intrinsic parameter “road density coefficient” from devices of a plurality of vehicles.

The preprocessor 180 may derive data “road density coefficient” as the representative intrinsic parameter by preprocessing the collected vehicle speed data.

Referring to FIG. 1 and FIG. 2 again, the update unit 160 may update the at least one representative intrinsic parameter based on the collected real sensor data related to the representative intrinsic parameter and the estimated output value of the representative intrinsic parameter.

The update unit 160 may update the at least one representative intrinsic parameter based on the real sensor data related to the preprocessed representative intrinsic parameter. For example, referring to FIG. 3A through FIG. 3C, the update unit 160 may update the intrinsic parameter “elastic modulus” (an internal parameter of the simulation model) based on the natural frequency obtained by preprocessing the acceleration data collected from the real model of the bridge 303 and the estimated output value of the intrinsic parameter “elastic modulus” selected as the representative intrinsic parameter. Referring to FIG. 4A and FIG. 4B, the update unit 160 may update the intrinsic parameter “road density coefficient” (an internal parameter of the simulation model) based on the road density coefficient (link speed) obtained by preprocessing the vehicle speed data collected from the devices of the plurality of vehicles and the estimated output value (link speed) of the intrinsic parameter “road density coefficient” selected as the representative intrinsic parameter.

The update unit 160 may recalculate and update the at least one representative intrinsic parameter so that an error between the real sensor data related to the preprocessed representative intrinsic parameter and the estimated output value of the representative intrinsic parameter can be minimized. Herein, the update unit 160 may use an optimization algorithm to recalculate the representative intrinsic parameter so that an error between the real sensor data related to the preprocessed representative intrinsic parameter and the estimated output value of the representative intrinsic parameter can be minimized. For example, when a simulation of a bridge is performed, preprocessed real sensor data may correspond to a natural frequency derived by preprocessing acceleration data and measured at the real bridge. Also, an estimated output value of a representative intrinsic parameter may refer to the model's natural frequency depending on the representative intrinsic parameter (elastic modulus) of a simulation model of the bridge. Further, the recalculation may include 1) calculating an error between the natural frequency derived by preprocessing the acceleration data and the model's natural frequency of the simulation model (initial model) of the bridge, 2) adjusting the representative intrinsic parameter to reduce the error, 3) recalculating the model's natural frequency by performing the simulation again, and 4) repeating a series of processes until the error satisfies a minimum reference and twinning, to the simulation model of the bridge, a representative intrinsic parameter obtained when the error is minimized.

The simulation unit 170 may perform a simulation by applying the updated representative intrinsic parameter to the simulation model.

The output unit 120 may output an estimated output value which can be produced from the simulation model to which the updated representative intrinsic parameter is applied depending on an input value. For example, referring to FIG. 3A through FIG. 3C, when an input value of an intrinsic parameter (e.g., temperature, force, and the like) related to a bridge is input into a bridge simulation model to which the updated representative intrinsic parameter is applied, the output unit 120 may output an estimated output value (displacement depending on the input of each intrinsic parameter) that can be produced depending on the input value. Referring to FIG. 4A and FIG. 4B, when an input value of an intrinsic parameter “signal cycle” related to a situation at an intersection is input into an intersection simulation model to which the updated representative intrinsic parameter “road density coefficient” is applied, the output unit 120 may output a signal passing time that can be produced depending on the input value.

The surrogate model creation unit 190 may create a plurality of surrogate models corresponding to a plurality of preset scenarios based on a simulation model (completed simulation) to which the updated representative intrinsic parameter is applied. Herein, the surrogate model is a model abstracted based on a relationship between an input value of a simulation to which an updated representative intrinsic parameter is applied and a simulation result depending on the input value. Compared to the simulation model to which the updated representative intrinsic parameter is applied, the surrogate model has a short execution time, can be executed in real time, and does not require a separate license. Therefore, the surrogate model can solve the license problem with the simulation engine. For example, the surrogate model creation unit 190 may create a plurality of surrogate models (e.g., Naju Pyeongsu Bridge model, Jecheon Third Susan Bridge model, and the like) from the bridge simulation model to which the updated representative intrinsic parameter “elastic modulus” is applied.

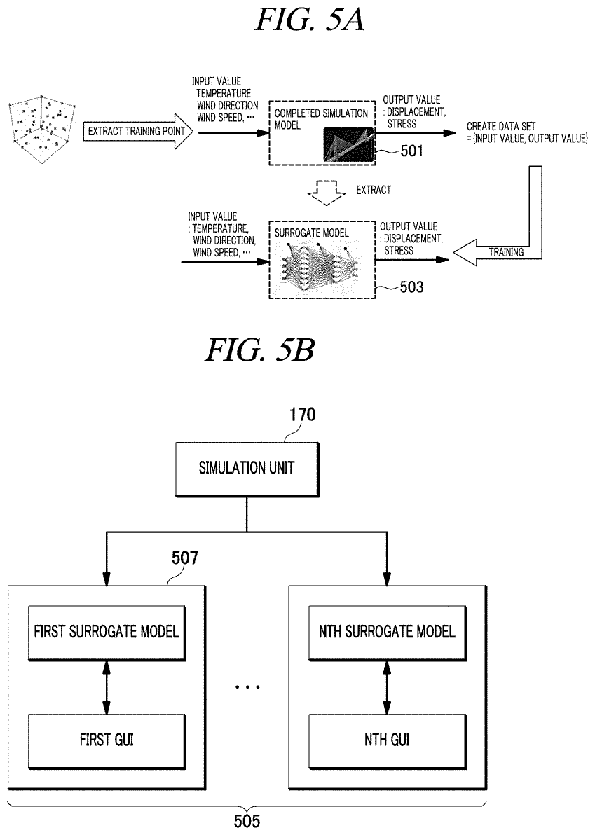

For example, referring to FIG. 5A, when data on a target model to be simulated (e.g., temperature, wind direction, wind speed, and the like) are input as input values of a completed simulation model 501, the surrogate model creation unit 190 may construct training data for training a surrogate model 503 by mapping the input values with output values (e.g., displacement, stress, and the like) depending on the input values through a data set. The surrogate model creation unit 190 may train the surrogate model 503 based on the input values and output values included in the training data constructed from the completed simulation model 501. Specifically, the surrogate model creation unit 190 may input an input value included in the training data into the surrogate model 503 and train the surrogate model 503 so that an output value from the surrogate model 503 can be output as an output value included in the training data.

The simulation unit 170 may provide a simulation model to which the updated representative intrinsic parameter is applied and a simulation result from the surrogate model on a GUI screen (e.g., a web page).

When any one of preset scenarios is selected, the simulation unit 170 may perform a simulation according to the selected scenario by inputting an input value into the simulation model to which the updated representative intrinsic parameter is applied.

For example, referring to FIG. 5B, if there is a plurality of surrogate models 505, the simulation unit 170 may perform a simulation using a surrogate model 507 selected from among the plurality of surrogate models 505 (e.g., Naju Pyeongsu Bridge model, Jecheon Third Susan Bridge model, and the like) related to a first scenario (e.g., a bridge scenario) selected from among a plurality of preset scenarios (e.g., bridge scenarios, intersection scenarios, building scenarios, and the like) based on a first completed simulation model corresponding to the selected first scenario, and provide a simulation result from the surrogate model 507 on a first GUI screen.

Meanwhile, it would be understood by a person with ordinary skill in the art that each of the creation unit 100, the identification unit 110, the output unit 120, the correlation analysis unit 130, the selection unit 140, the collection unit 150, the update unit 160, the simulation unit 170, the preprocessor 180 and the surrogate model creation unit 190 can be implemented separately or in combination with one another.

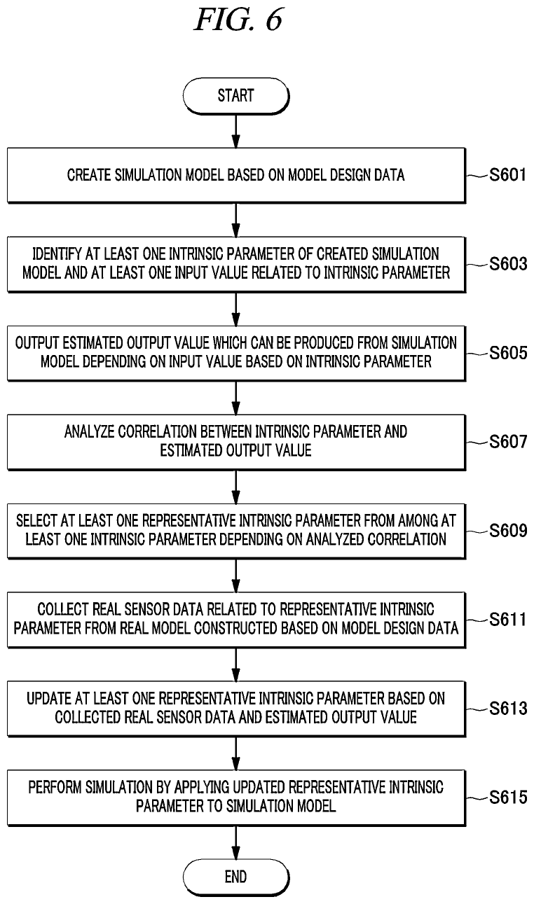

FIG. 6 is a flowchart illustrating a method for performing a simulation in accordance with an embodiment of the present disclosure.

Referring to FIG. 6, the simulation device 10 may create a simulation model based on model design data in process S601.

In process S603, the simulation device 10 may identify at least one intrinsic parameter of the created simulation model and at least one input value related to the intrinsic parameter.

In process S605, the simulation device 10 may output an estimated output value which can be produced from the simulation model depending on the input value related to the intrinsic parameter based on the intrinsic parameter for each intrinsic parameter.

In process S607, the simulation device 10 may analyze a correlation between the intrinsic parameter and the estimated output value for each intrinsic parameter.

In process S609, the simulation device 10 may select at least one representative intrinsic parameter from among the at least one intrinsic parameter depending on the analyzed correlation.

In process S611, the simulation device 10 may collect real sensor data related to the representative intrinsic parameter from a real model constructed based on the model design data.

In process S613, the simulation device 10 may update the at least one representative intrinsic parameter based on the collected real sensor data related to the representative intrinsic parameter and the estimated output value of the representative intrinsic parameter.

In process S615, the simulation device 10 may perform a simulation by applying the updated representative intrinsic parameter to the simulation model.

In the descriptions above, processes S601 through S615 may be divided into additional processes or combined into fewer processes depending on an embodiment. In addition, some of the processes may be omitted and the sequence of the processes may be changed if necessary.

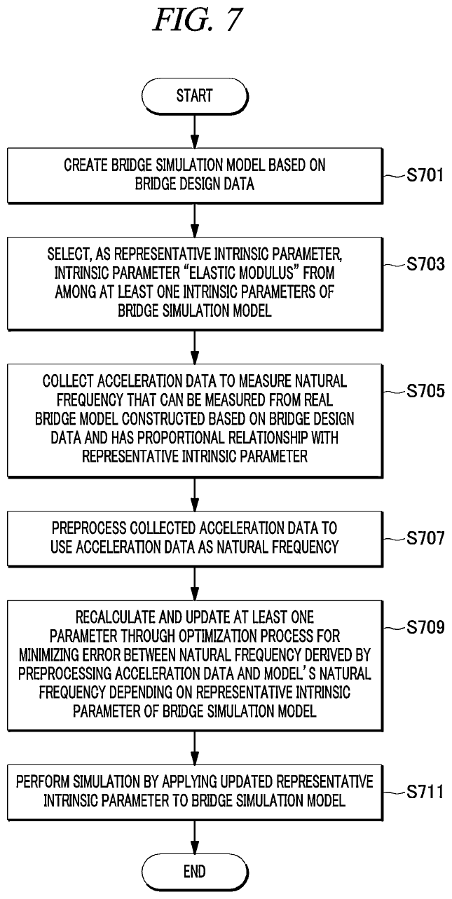

FIG. 7 is a flowchart illustrating a method for performing a simulation of a bridge in accordance with an embodiment of the present disclosure.

Referring to FIG. 7, the simulation device 10 may create a bridge simulation model based on bridge design data in process S701.

In process S703, the simulation device 10 may select, as a representative intrinsic parameter, an intrinsic parameter “elastic modulus” from among a plurality of intrinsic parameters of the bridge simulation model.

In process S705, the simulation device 10 may collect acceleration data to measure a natural frequency that can be measured from a real bridge model constructed based on the bridge design data and has a proportional relationship with the intrinsic parameter (elastic modulus).

In process S707, the simulation device 10 may preprocess the collected acceleration data to use the acceleration data as a natural frequency.

In process S709, the simulation device 10 may recalculate and update the at least one parameter through an optimization process for minimizing an error between the natural frequency derived by preprocessing the acceleration data and the model's natural frequency depending on the representative intrinsic parameter (elastic modulus) of the bridge simulation model.

In process S711, the simulation device 10 may perform a simulation by applying the updated representative intrinsic parameter to the bridge simulation model.

In the descriptions above, processes S701 through S711 may be divided into additional processes or combined into fewer processes depending on an embodiment. In addition, some of the processes may be omitted and the sequence of the processes may be changed if necessary.

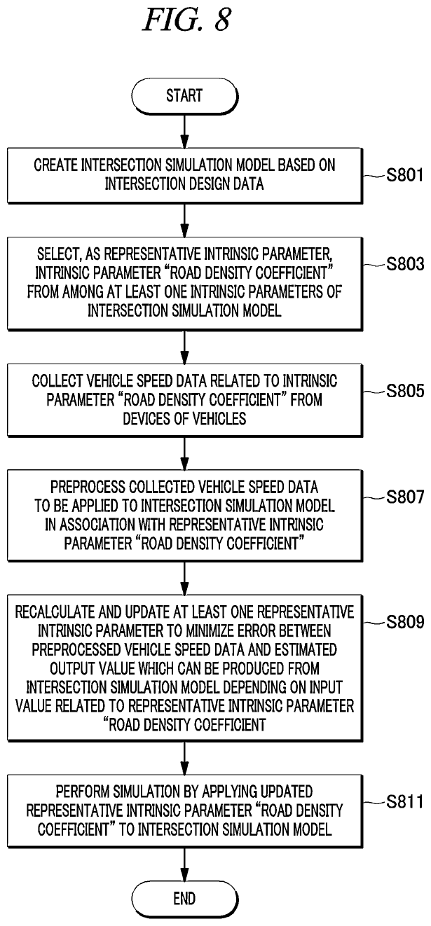

FIG. 8 is a flowchart illustrating a method for performing a simulation of an intersection in accordance with an embodiment of the present disclosure.

Referring to FIG. 8, the simulation device 10 may create an intersection simulation model based on intersection design data in process S801.

In process S803, the simulation device 10 may select, as a representative intrinsic parameter, an intrinsic parameter “road density coefficient” from among a plurality of intrinsic parameters of the intersection simulation model.

In process S805, the simulation device 10 may collect vehicle speed data related to the intrinsic parameter “road density coefficient” from devices of a plurality of vehicles.

In process S807, the simulation device 10 may preprocess the collected vehicle speed data to be applied to the intersection simulation model in association with the at least one representative intrinsic parameter “road density coefficient”.

In process S809, the simulation device 10 may recalculate and update the at least one representative intrinsic parameter to minimize an error between the preprocessed vehicle speed data (link speed) and an estimated output value (link speed) which can be produced from the intersection simulation model depending on an input value related to the representative intrinsic parameter “road density coefficient”.

In process S811, the simulation device 10 may perform a simulation (i.e., a simulation for estimating the number of internal vehicles located in internal and external links and the number of vehicles incoming from the outside) by applying the updated representative intrinsic parameter “road density coefficient” to the intersection simulation model.

In the descriptions above, the processes S801 to S811 may be divided into additional processes or combined into fewer processes depending on an embodiment. In addition, some of the processes may be omitted and the sequence of the processes may be changed if necessary.

A computer-readable medium can be any usable medium which can be accessed by the computer and includes all volatile/non-volatile and removable/non-removable media. Further, the computer-readable medium may include all computer storage and communication media. The computer storage medium includes all volatile/non-volatile and removable/non-removable media embodied by a certain method or technology for storing information such as computer-readable instruction code, a data structure, a program module or other data. The communication medium typically includes the computer-readable instruction code, the data structure, the program module, or other data of a modulated data signal such as a carrier wave, or other transmission mechanism, and includes a certain information transmission medium.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A simulation device that performs a simulation based on a digital twin service, comprising:
a creation unit configured to create a simulation model based on model design data;
an identification unit configured to identify at least one intrinsic parameter of the created simulation model and at least one input value related to the intrinsic parameter;
an output unit configured to output an estimated output value which is produced from the simulation model depending on the input value based on the intrinsic parameter;
a correlation analysis unit configured to analyze a correlation between the intrinsic parameter and the estimated output value;
a selection unit configured to select at least one representative intrinsic parameter from among the at least one intrinsic parameter depending on the analyzed correlation;
a collection unit configured to collect real sensor data related to the representative intrinsic parameter from a real model constructed based on the model design data;
an update unit configured to update the at least one representative intrinsic parameter based on the collected real sensor data and the estimated output value; and
a simulation unit configured to perform a simulation by applying the updated representative intrinsic parameter to the simulation model.

2. The simulation device of claim 1,
wherein the output unit is further configured to set a range of variation of the at least one intrinsic parameter and output an estimated output value which is produced, depending on the input value, from the simulation model to which the set range of variation of the intrinsic parameter is applied.

3. The simulation device of claim 1,
wherein the correlation analysis unit is further configured to derive a distribution map of the estimated output value in relation to each intrinsic parameter depending on the input value for each intrinsic parameter, derive a correlation between the intrinsic parameter and the estimated output value by analyzing the derived distribution map.

4. The simulation device of claim 1, further comprising:
a preprocessor configured to preprocess the collected real sensor data to be applied to the simulation model in association with the at least one representative intrinsic parameter,
wherein the update unit is further configured to update the at least one representative intrinsic parameter based on the preprocessed real sensor data.

5. The simulation device of claim 4,
wherein the update unit is further configured to recalculate and update the at least one representative intrinsic parameter to minimize an error between the preprocessed real sensor data and the estimated output value.

6. The simulation device of claim 5,
wherein the output unit is further configured to output the estimated output value which is produced, depending on the input value, from the simulation model to which the updated representative intrinsic parameter is applied.

7. The simulation device of claim 1,
wherein when any one of preset scenarios is selected, the simulation unit is further configured to perform a simulation according to the selected scenario by inputting the input value into the simulation model to which the updated representative intrinsic parameter is applied.

8. A simulation method for performing a simulation based on a digital twin service, comprising:
creating a simulation model based on model design data;
identifying at least one intrinsic parameter of the created simulation model and at least one input value related to the intrinsic parameter;
outputting an estimated output value which is produced, depending on the input value, from the simulation model based on the intrinsic parameter;
analyzing a correlation between the intrinsic parameter and the estimated output value;
selecting at least one representative intrinsic parameter from among the at least one intrinsic parameter depending on the analyzed correlation;
collecting real sensor data related to the representative intrinsic parameter from a real model constructed based on the model design data; and
updating the at least one representative intrinsic parameter based on the collected real sensor data and the estimated output value.

9. The simulation method of claim 8,
wherein the outputting an estimated output value includes:
setting a range of variation of the at least one intrinsic parameter and outputting an estimated output value which is produced depending on the input value from the simulation model to which the set range of variation of the intrinsic parameter is applied.

10. The simulation method of claim 8,
wherein the analyzing a correlation includes:
deriving a distribution map of the estimated output value in relation to each intrinsic parameter depending on the input value for each intrinsic parameter, and
deriving a correlation between the intrinsic parameter and the estimated output value by analyzing the derived distribution map.

11. The simulation method of claim 8, further comprising:
preprocessing the collected real sensor data to be applied to the simulation model in association with the at least one representative intrinsic parameter,
wherein the updating the representative intrinsic parameter includes: updating the at least one representative intrinsic parameter based on the preprocessed real sensor data.

12. The simulation method of claim 11,
wherein the updating the representative intrinsic parameter includes:
recalculating and updating the at least one representative intrinsic parameter to minimize an error between the preprocessed real sensor data and the estimated output value.

13. The simulation method of claim 12,
wherein the outputting an estimated output value includes:
outputting the estimated output value which is produced depending on the input value from the simulation model to which the updated representative intrinsic parameter is applied.

14. The simulation method of claim 8, further comprising:
selecting any one of preset scenarios; and
performing a simulation according to the selected scenario by inputting the input value into the simulation model to which the updated representative intrinsic parameter is applied.

15. A computer-readable recording medium having stored thereon computer-executable instructions that, in response to execution, cause a computing device to create a simulation model based on model design data,
wherein the computer-executable instructions cause the computing device to:
identify at least one intrinsic parameter of the created simulation model,
select at least one representative intrinsic parameter from among the at least one identified intrinsic parameter,
collect real sensor data related to the representative intrinsic parameter from a real model constructed based on the model design data,
update the at least one representative intrinsic parameter based on the collected real sensor data, and
perform a simulation by applying the updated representative intrinsic parameter to the simulation model.
